(19) United States
(12) Patent Application Publication
(10) Pub. No.: US 2006/0289981 A1
(43) Pub. Date: Dec. 28, 2006

(54) Packaging logic and memory integrated circuits

(76) Inventors: Robert M. Nickerson, Chandler, AZ (US); Brian Taggart, Phoenix, AZ (US); Ronald I. Spreitzer, Phoenix, AZ (US)

Correspondence Address: TROP PRUNER & HU, PC, 1616 S. VOSS ROAD, SUITE 750, HOUSTON, TX, 77057-2631, US

(21) Appl. No.: 11/168,784

(22) Filed: Jun. 28, 2005

(51) Int. Cl. H01L 23/48

(52) U.S. Cl. 257/686; 257/737; 257/698

(57) ABSTRACT

Logic and memory may be packaged together in a single integrated circuit package that, in some embodiments, has high input/output pin count and low stack height. In some embodiments, the logic may be stacked on top of the memory which may be stacked on a flex substrate. Such a substrate may accommodate a multilayer interconnection system which facilitates high pin count and low package height. In some embodiments, the package may be wired so that the memory may only be accessed through the logic.

### BACKGROUND

This invention relates generally to semiconductor packages which include both a logic die and at least one memory die.

A logic die may be a processor, such as an applications processor or a baseband processor, for a cellular telephone. In order to operate, a logic die uses memory to store information. In some cases, the memory and the logic may be packaged together in a single package. This may have many advantages including increased performance and lower cost, as well as more compact configuration.

There is always a need for smaller packages that support higher pin or input/output counts. Semiconductor packages communicate with the outside world through input/outputs. The more input/outputs, the more signals that can be provided and, in some cases, the more efficient or complex the operations that may be implemented. Since the packages are relatively small and the die within the package is even smaller, the provision of high input/output counts can be complex.

### BRIEF DESCRIPTION OF THE DRAWINGS

FIG. 1 is an enlarged, top plan view of one embodiment of the present invention;

FIG. 2 is across-sectional view taken generally along the line 2-2 in FIG. 1 in accordance with one embodiment of the present invention; and

FIG. 3 is a system depiction in accordance with one embodiment.

### DETAILED DESCRIPTION

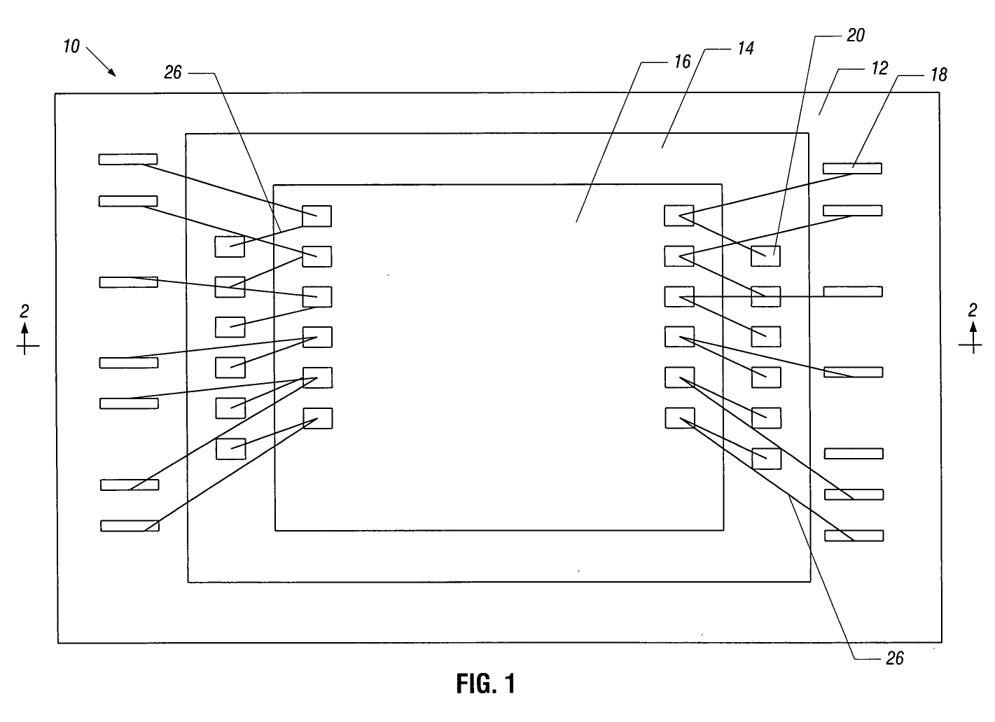

Referring to FIG. 1, a stacked semiconductor chip package 10 may include a flex substrate 12 formed of flexible tape or a laminate substrate. The substrate 12 may include bond fingers 18 which are wire bonded by wire bonds 26. In one embodiment, the substrate 12 may be a flexible or polyimide substrate. Such packages are flexible, as opposed to rigid packages, which may be made of bismaleimide triazine (BT).

As used herein, a “flex substrate” includes a polymer layer and a circuit formed on one surface of said polymer layer. A flex circuit is more flexible that a rigid or BT package. For example, laminated flex substrates may be formed of polyimide or polyester and one or more metallization layers.

The next layer in the package 10 is formed by a die or integrated circuit 14 which may be a memory integrated circuit. It includes bond pads 20. The bond pads 20 are, in turn, coupled by wire bonds 26 to an upper or logic integrated circuit 16. The upper or logic die or integrated circuit 16 may, for example, be an applications processor for a cellular telephone.

Thus, in some embodiments, the logic, as well as the memory that works with the logic, are packaged together in a close knit, efficient arrangement. Communications between the logic and the memory may flow through relatively short wire bonds 26. Moreover, the stepped, easily wire bonded configuration may be achieved by making the die size of the memory integrated circuit 14 larger than the die size of the logic integrated circuit 16.

The connections from the substrate 12 to the memory integrated circuit 14 are only by way of the logic integrated circuit 16 in some embodiments. In those embodiments, this contacting of the memory integrated circuit through the logic integrated circuit may have many advantages, including preventing access to the memory except via the logic. Such an arrangement may prevent undesired modification of the memory that would adversely affect performance of the package 10 and the reputation of its manufacturer. In addition, better security may be achieved by controlling access to the memory. Accessing the memory via logic may also reduce the number of bond fingers, which may translate into a smaller substrate footprint and lower associated costs. Accessing the memory through the logic may also eliminate or shorten the wire bond length, reducing costs and wire sweep, while improving electrical performance. The reduced bond finger count may result in reduced external pin count, reducing cost and size.

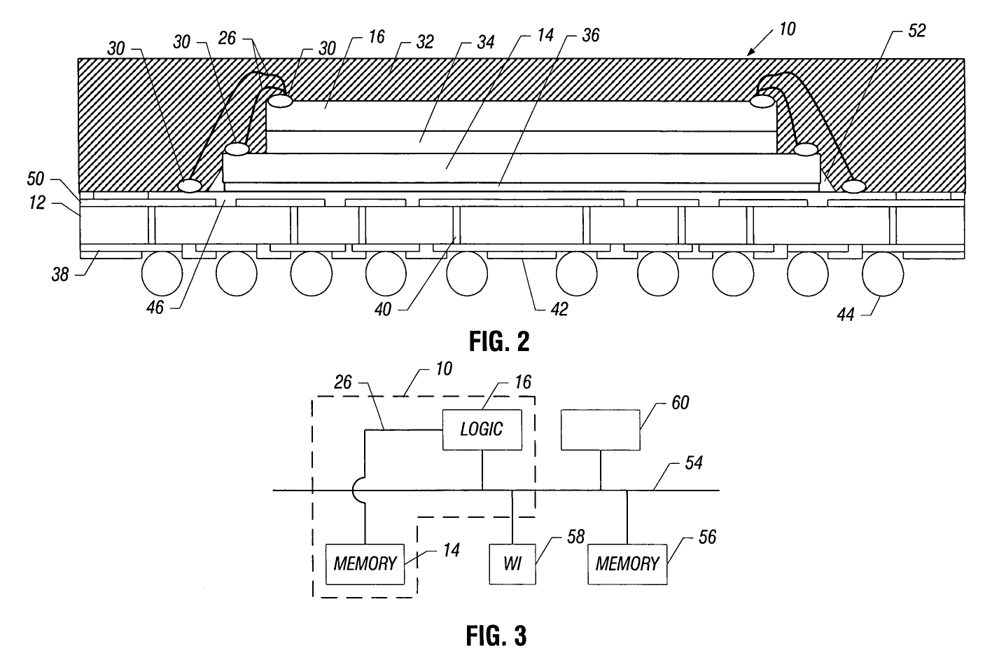

Referring to FIG. 2, the structure shown in FIG. 1 may be encapsulated within a suitable encapsulant 32 in some cases. Among the suitable encapsulants 32 are glass particle filled epoxy resins, bisbenzocyclobutane, polyimide, silicone rubber, low dielectric constant dielectrics, and others.

Electrical connection to the package 10 may be by way of external pins 44. In one embodiment, the pins 44 may be in the form of solder balls. An insulator 42 separates the pins 44 that fit within gaps between adjacent insulators 42.

Over the insulators 42 may be an interconnection layer 38 that may amount to a plated metallization, allowing for routing of signals to and from the pins 44 to an upper metallization layer 50 within the substrate 12. Bond pads 46 allow interconnection between wire bonds 26, the upper metallization layer 50, and the lower metallization layer 38. More particularly, vias 40 selectively connect metallizations within the two layers 50 and 38. On top, the wire bonds 26 are soldered at 30 to the contacts 46.

The memory integrated circuit 14 may be secured to the substrate 12 by a die attach 36 or any other suitable adherent including adhesive or adhesive coated tape. Then, the logic integrated circuit 16 may be secured to the memory integrated circuit 14 by another die attach 34 that, again, may also be any suitable adherent. Thereafter, wire bonds 26 may be formed from the substrate 12 to the logic integrated circuit 16 and then from the logic integrated circuit 16 down to the memory integrated circuit 14. In some embodiments, additional adhesive 52 may also be applied between the circuit 14 and the substrate 12.

In some embodiments, input/output pin counts may exceed 300, which is extremely dense packaging made possible by the use of the flex substrate 12. The manufacturing process of the flex substrate 12 enables tighter routing density within the substrate to accommodate the higher input/output pin counts as compared to a conventional laminate substrate. In addition, a relatively low package stack height of less than 1.2 millimeters may be achieved. Stack height is measured from the top of die 16 to the upper surface of a printed circuit board (not shown) to which the package 10 is surface mounted. Reduced costs may be obtained by various combinations of features described herein in some embodiments. Finally, access to the memory may be controlled through the logic integrated circuit in some embodiments.

Referring to FIG. 3, a processor-based system may be any of a variety of processor-based systems, including a cellular telephone. In a cellular telephone embodiment, the logic integrated circuit 16 may be an applications processor connected by the wire bond 26 to the memory integrated circuit 14, all included within a single package 10. However, the logic integrated circuit 16 may be connected through the substrate 12 to another logic integrated circuit 60. In a cellular telephone embodiment, the logic integrated circuit 60 may be a baseband processor. The connection may use a bus 54 in some embodiments.

Also coupled to the bus 54 may be a memory 56 which may, for example, service the logic integrated circuit 60. Also coupled to the bus 54 may be a wireless interface 58 such as a dipole antenna.

In some embodiments, a relatively high pin count may be achieved by packaging the memory integrated circuit 14 and the logic integrated circuit 16 in one package 10 with a substrate 12. That package 10 may then be coupled by the pins 44 to a printed circuit board having the other components including the bus 54.

Any attempt to access the memory integrated circuit 14 may be only via the logic integrated circuit 16 in some embodiments, providing higher security and preventing unauthorized accessing of the memory integrated circuit. This controlled memory access may avoid performance issues caused by using the memory integrated circuit for applications other than supporting the logic integrated circuit 16.

A multilayer polyimide flex substrate 12 may be designed to work in high density stack chip package for high input/output pin logic and memory chip stacks in some embodiments. The substrate 12 may be manufactured using flex substrate process steps. At assembly, the multilayer polyimide base substrate is cut into strips and inserted into carriers. Then, flex molded matrix array packaging assembly processes may be used. However, more than one piece of silicon may be stacked, including at least one logic and one memory silicon, using standard or special die attach process techniques, with or without spacers. Then, the chips may be wire bonded as dies are stacked using standard die attach process steps. Finally, the molding or encapsulating is completed. This may be followed by ball attach and singulation.

Although a surface mount or chip stack package is illustrated, other package styles may also be used. Other package types include land grid and solder ball grid array packages.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom including scaling this concept to include multiple memory silicon and logic silicon stacked within a semiconductor package with dedicated access features. It is intended that the appended claims cover all such modifications and variations as fall within the true spirit and scope of this present invention.

What is claimed is:

1. A method comprising:
stacking a logic die over a memory die;
securing said memory die to a multilayer polyimide substrate, and
enabling said logic die to control access to said memory die.

2. The method of claim 1 including forming wire bonds from said substrate to said logic die.

3. The method of claim 2 including wire bonding from said logic die to said memory die.

4. The method of claim 1 including only providing electrical connections to said memory die through said logic die.

5. The method of claim 1 including providing more than 300 input/outputs to said logic die.

6. The method of claim 1 including forming a package with said stacked logic and memory dice, having a stack height of less than 1.2 millimeters.

7. The method of claim 1 including using said logic die as an applications processor.

8. The method of claim 1 including using solder balls on said substrate.

9. (canceled)

10. A packaged integrated circuit comprising:
a flex substrate wherein said flex substrate includes multiple interconnection layers in a polyimide substrate;
a memory die secured to said substrate; and
a logic die secured to said memory die, said logic die adapted to control access to said memory die.

11. The circuit of claim 10 wherein said memory die is larger than said logic die.

12. The circuit of claim 10 including solder balls on said substrate.

13. The circuit of claim 10 wherein wire bonds are formed from said substrate to said logic die.

14. The circuit of claim 13 wherein a plurality of wire bonds are formed from said logic die to said memory die.

15. The circuit of claim 14 wherein electrical connections from said substrate to said memory die are only made by way of said logic die.

16. The circuit of claim 10 wherein said logic die is an applications processor for a cellular telephone.

17. The circuit of claim 10 including more than 300 input/outputs to said logic die.

18. The circuit of claim 10 wherein said circuit has a stack height of less than 1.2 millimeters.

19. (canceled)

20. A system comprising:
a baseband processor;
a memory associated with said baseband processor;
an integrated circuit package coupled to said baseband processor, said package including an applications processor die on top of a memory die, said package including a flex substrate and said applications processor to control access to said memory die and wherein said flex substrate includes at least two metallization layers and said substrate includes polyimide; and
a wireless interface.

21. The system of claim 20 wherein said system is a cellular telephone.

22. The system of claim 20 including a bus coupling said baseband processor to said memory.

23. The system of claim 20 wherein said package has a stack height of less than 1.2 millimeters.

24. The system of claim 20 including over 300 input/outputs to said applications processor die.

25-26. (canceled)

27. The system of claim 20 wherein said memory die is only accessible by way of said applications processor die.

28. The system of claim 20 wherein said substrate is wire bonded to said applications processor die and said applications processor die is wire bonded to said memory die.

29. The system of claim 20 wherein said package includes solder balls.

30. The system of claim 20 wherein said applications processor die is smaller than said memory die.
